(19) United States
(12) Patent Application Publication
(10) Pub. No.: US 2026/0271472 A1
(43) Pub. Date: Sep. 10, 2026

(54) NEURAL SIGNAL AMPLIFICATION DEVICE AND A METHOD OF FABRICATING THEREOF

(71) Applicant: Advanced Biomedical Instrumentation Centre Limited, Hong Kong (CN)

(72) Inventors: Kwok Leung Chan, Pokfulam, Hong Kong (CN); Yifan Guo, Hong Kong (CN)

(21) Appl. No.: 19/554,717

(22) Filed: Mar. 3, 2026

Related U.S. Application Data
(60) Provisional application No. 63/768,616, filed on Mar. 7, 2025.

(51) Int. Cl. H10K 10/46; H10K 10/88

(52) U.S. Cl. CPC H10K 10/466; H10K 10/88

(57) ABSTRACT

A neural signal amplification device includes a substrate having an organic field-effect transistor (OFET) disposed on the substrate, the OFET having a gate arranged to receive neural signals and a gate dielectric layer disposed between the gate and a semiconductor layer, wherein the OFET is arranged to amplify the neural signals received at the gate, wherein the substrate includes a flexible polymeric material arranged to conform to a surface of a subject's brain.

### TECHNICAL FIELD

The present invention relates to a neural signal amplification device and particularly, although not exclusively, to a signal amplification device for use with electrodes used in brain-computer interfaces (BCI) for the on-site amplification of neural signals.

### BACKGROUND

Brain-computer interfaces (BCI) devices are medical devices that are designed to be implanted into a patient subject so as to record neural signals of the patient's brain. These devices may be designed to be surgically placed within the patient's brain such that electrodes will read and record neural signals of the patient. The devices may be useful in the treatment of certain neurological conditions such as epilepsy as medical professionals can take these signals from device to devise a treatment plan for the patient.

However, the surgical implantation of this electrode is not without risk as it requires an invasive procedure of opening an aperture in the skull of the patient to insert the device. Furthermore, a significant challenge is in getting a sufficient amount of useful information from the electrode. Given the physical characteristics of the neural signals, and the challenges of reading these signals with a device that is suitable for insertion into the brain tissue of the patient, these challenges have meant that the use of BCIs are often considered a complex procedure that is used as a last resort.

### SUMMARY OF THE INVENTION

In accordance with a first aspect of the present invention, there is provided a neural signal amplification device comprising:
a substrate having an organic field-effect transistor (OFET) disposed on the substrate, the OFET having a gate arranged to receive neural signals and a gate dielectric layer disposed between the gate and a semiconductor layer, wherein the OFET is arranged to amplify the neural signals received at the gate.

In an embodiment of the first aspect, the substrate comprises a flexible polymeric material arranged to conform to a surface of a subject's brain.

In an embodiment of the first aspect, the gate dielectric layer comprises a solid dielectric material arranged to electrically isolate biological tissue from the semiconductor layer.

In an embodiment of the first aspect, the semiconductor layer comprises an organic single-crystal structure arranged to provide enhanced charge-carrier mobility.

In an embodiment of the first aspect, the OFET is electrically coupled to a load element to amplify the neural signals received at the gate.

Preferably, the load element, when coupled to the OFET defines an inverter-type amplifier circuit.

In an embodiment of the first aspect, the organic single-crystal structure of the semiconductor layer comprises 2,9-didecyldinaphtho[2,3-b: 2,3′-f]thieno[3,2-b]thiophene (C10-DNTT).

In an embodiment of the first aspect, the solid dielectric material comprises a high-κ metal oxide.

In an embodiment of the first aspect, the high-κ metal oxide comprises hafnium oxide (HfO₂) deposited by atomic layer deposition.

In an embodiment of the first aspect, the organic single-crystal structure comprises a solution sheared film having aligned molecular layers to minimize grain boundaries within a channel region defined between a source electrode and a drain electrode of the OFET.

In an embodiment of the first aspect, the device further comprises an encapsulation layer covering the OFET and the amplification element, the encapsulation layer having an opening exposing a portion of the gate to define a sensing area for contact with biological tissue.

In an embodiment of the first aspect, the encapsulation layer comprises Parylene-C having a thickness of less than 10 μm.

In an embodiment of the first aspect, the OFET defines a channel length of approximately 5 μm between a source electrode and a drain electrode.

In an embodiment of the first aspect, the device further comprises a DC offset voltage source coupled to the amplification element and arranged to shift a transition voltage of the amplification element to align with a baseline voltage of the neural signals.

In an embodiment of the first aspect, the load element comprises a resistor having a resistance value matched to an on-resistance of the OFET.

In an embodiment of the first aspect, a source electrode and a drain electrode of the OFET are extended away from the gate to reduce electrical crosstalk between the neural signals and driving currents of the OFET.

In an embodiment of the first aspect, the semiconductor layer comprises a multilayer stack of C10-DNTT molecules.

In an embodiment of the first aspect, the multilayer stack comprises four molecular layers.

In accordance with a second aspect of the invention, there is provided a method of fabricating a neural amplification device of the first aspect, comprising the steps of:
spin coating polyimide (PI) onto a SiO2/Si wafer as a flexible substrate;
depositing electrodes, including a gate onto the PI;
depositing a high-κ hafnium oxide (HfO2) over the PI and the electrodes;
depositing C10-DNTT single crystals onto the high-κ HfO2;
solution shearing the C10-DNTT single crystals;
patterning the solution sheared organic single-crystals using photolithography;
depositing source/drain electrodes;
etching the HfO2 on the sensing area at the gate; and
encapsulating the device with biocompatible materials whilst leaving a sensing area at the gate exposed.

In an embodiment of the second aspect, the encapsulating biocompatible material is parylene-C.

In an embodiment of the second aspect, the electrodes are formed by depositing gold onto the PI.

### BRIEF DESCRIPTION OF THE DRAWINGS

Embodiments of the present invention will now be described, by way of example, with reference to the accompanying drawings in which:

FIG. 1 illustrates the amplification procedure in accordance with one example embodiment of the present invention, which is a neural signal amplification device; In part (a), there is shown an illustration of a nerve cell model generating neural signals, and in part(b), there is shown a schematic of an OFET-based amplification circuit in accordance with one embodiment of the invention.

FIG. 2 illustrates the fabrication process and the structure of the device of FIG. 1; In part (a), there is shown the step-by-step fabrication procedures to make the device; (b) is an illustration of the OFET structure of the device; (c) is an optical image of the OFETs used in the device; (d) shows an example of the device placed on paper for illustration; (e) shows the device on a brain model; (f) is a rendered cross-sectional STEM image; and (g) shows corresponding EDS elemental mapping.

FIG. 3 illustrates the characterization of the OFETs-based amplifier; in part (a) there is a polarized optical microscope (POM) image; In (b) there is a rendered STEM image of the channel; (c) shows areal capacitance and leakage current density; (d) is an AFM image of the substrate; (e) shows 2D GIWAXS results; (f) is a schematic of the molecular package; (g) shows the relationship between shearing speed and thickness; (h) shows a double-sweep transfer curve; (i) shows transfer curves after soaking; and (j) shows the change of gₘ with time in 1×PBS solution. The inset diagram is the optical image of the device during testing.

FIG. 4 illustrates an example in-vitro evaluation of the neural signal amplification device; (a) shows voltage transfer curves of the inverter; (b) shows the gain; (c) is a schematic of the input voltage optimization strategy; (d) shows gain before and after DC offset and the inset diagram shows the device with PCB connection and Ag/AgCl electrode during testing; (e) is the circuit diagram for in-vitro evaluation; and (f) shows a comparison of inputs vs. amplified output signals at different frequencies.

### DETAILED DESCRIPTION OF THE PREFERRED EMBODIMENT

Without wishing to be bound by theory, the inventors through trials, experimentations and research have found that in the design and usage of brain-computer interfaces (BCI), transducing elements play an important role in monitoring and recording neural signals of a patient subject. However, the monitoring and recording neural signals has challenges of noise in the signal, in turn, meaning the steps to obtain a high-quality signal for diagnosis or treatment purposes may be difficult. Accordingly, a neural interface that is insensitive to noise, has a high signal-to-noise ratio (SNR), and is compatible with full-frequency band monitoring will be desirable to medical practitioners.

Neural signals may be recorded using passive microelectrodes that are inserted into the patient's skull. These recorded signals may have amplitudes in the range of hundreds of microvolts and will need to be transmitted via cables or other electric channels to external circuits for processing. During this transmission, the fidelity and quality of the relatively weak brain signals may be compromised by noise and electromagnetic interference. To maintain a usable SNR, passive electrodes require expensive, sophisticated filters and bulky external amplifiers.

Active electrodes may address some of these concerns and are designed to use components such as transistors with transconductance (gₘ) and on-site amplification capabilities. These include organic electrochemical transistors (OECTs) and solution-gated field-effect transistors (SGFETs). While these devices offer high transconductance, they rely on the movement of ions for operation. In turn, the inventors have observed that these ionic transport mechanisms may significantly limit the operating frequency of the devices, such as restricting them to low frequencies (below 1 kHz). However, high-frequency signals, such as neural spikes (1-2 kHz), require much faster operating speeds (e.g., 20 kHz) for precise recording. Accordingly, the low frequencies of these devices may mean neural spikes or other high frequency signals are unable to be effectively monitored. Furthermore, ion-gated transistors may also exhibit significant hysteresis in their transfer curves, which compromises device stability during long-term testing. Finally, the direct interaction between the channel and biological fluids in some existing devices may lead to leakage currents that may be harmful to the underlying biological tissue as found in the patient's brain tissue. As patient safety is paramount, the risk of this harm may in turn reduce approval or adoption of such devices.

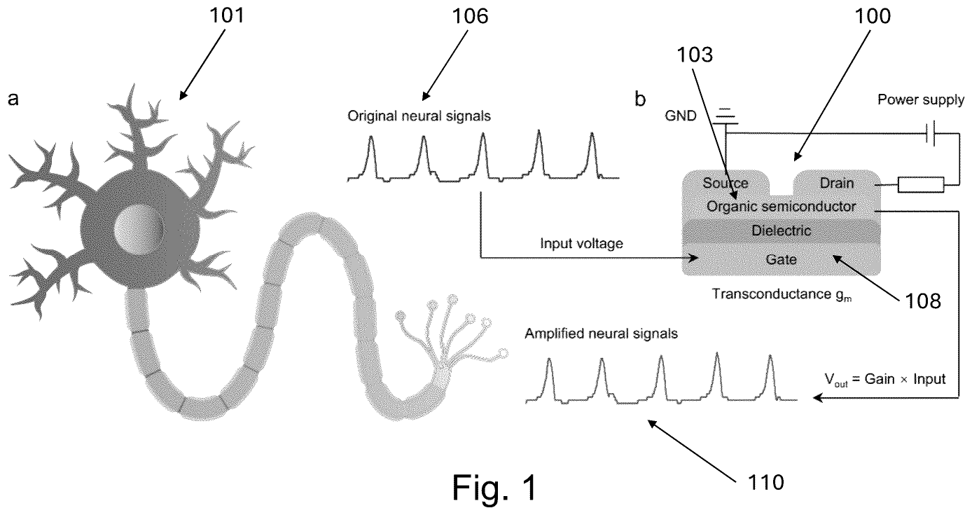

With reference to FIG. 1, there is illustrated at (a) an illustration of a nerve cell model 101 and at (b) an example embodiment a neural signal amplification device 100 comprising: a substrate having an organic field effect transistor (OFET) 103 disposed on the substrate, the OFET having a gate 108 arranged to receive neural signals and a gate dielectric layer disposed between the gate and a semiconductor layer; and an amplification element electrically coupled to the OFET and arranged to amplify the neural signals received at the gate.

In this embodiment as shown, the neural signal amplification device 100 is a flexible organic active electrode which includes a thin, conformal amplifier 102 built from organic field-effect transistors (OFETs) 104 that preferably uses an organic single-crystal (such as C10-DNTT) as the transistor channel to perform on-site amplification of neural signals 106 as obtained from a patient (for example, electrocorticography and spikes). As shown, the device 100 is implemented with a three-terminal active electrode that includes a gate 108, which operates as the sensing pad that amplifies 110 the microvolt-level brain signals 106 before they leave the tissue, in turn improving signal fidelity and signal to noise ratio (SNR).

Preferably, the neural signal amplification device 100 is an ultra-thin, flexible active electrode that integrates an organic field effect transistor (OFET) directly at the sensing site (e.g. brain tissue of the patient subject) to amplify neural signals before the signals leave the brain surface. The device may be implemented on a <10 μm polyimide/parylene C substrate and using a C10 DNTT organic single crystal semiconductor over a high k HfO₂ dielectric, although other or similar materials and dimensions are possible.

In use, the device 100 functions as a three-terminal amplifier in which the exposed gold pad serves as the gate 108. When microvolt level electrocorticography or spike signals 106 contact this pad 108, the signal modulate the OFET channel current and are in turn boosted through a compact resistive loaded inverter circuit. The input signals 106 are amplified owing to the transconductance (gₘ) of the OFETs. The amplification magnitude of the amplified signal 110 depends on the gain of the inverter (V_out=Gain×Input). This arrangement may solve the problem of low SNR that may be inherent in passive electrodes. Advantageously, this onsite amplification improves signal fidelity and signal to noise ratio (SNR) by strengthening the neural signal at the point of origin, avoiding degradation that may occur in passive electrodes during transmission. The device 100 is designed for conformal contact with curved brain tissue, which may enable stable, high bandwidth recording in liquid environments. In use, it may be placed on the cortical surface like a standard ECoG electrode, but instead of passively relaying signals, it actively amplifies the signals at the brain site whilst demonstrating multi-kilohertz (kHz) capability and stable operation in physiological conditions.

Preferably, the device operates by performing the following functions, including:
Sensing and transduction: the brain signal is applied directly to the OFET gate (the exposed gold sensing pad). The gate voltage modulates channel current in the OFET.
On-site amplification: the OFET is used in a resistive-loaded inverter configuration (a load resistor of 510 kΩ). Small input voltage swings at the gate produce larger voltage swings at the inverter output; the measured gain is ≈10 when the inverter supply (Vdd) is −3 V.
DC offset tuning: a small DC offset is applied to source/drain terminals to shift the inverter transition point to align with neural baseline levels (near 0 V), maximizing usable gain for millivolt/μV inputs.

In examples where these steps were performed and tested, it was noted that the device was able to operate such that 250 μV input signals at 100 Hz and 1 kHz were amplified over sixfold (output ≈1.5 mV) in 1×PBS during in-vitro tests. In turn, showing the device 100 may handle both low-frequency field potentials and higher-frequency spikes. OFETs here are selected by the inventors to avoid ion-transport limits of ion-gated transistors and to enable higher operating speed.

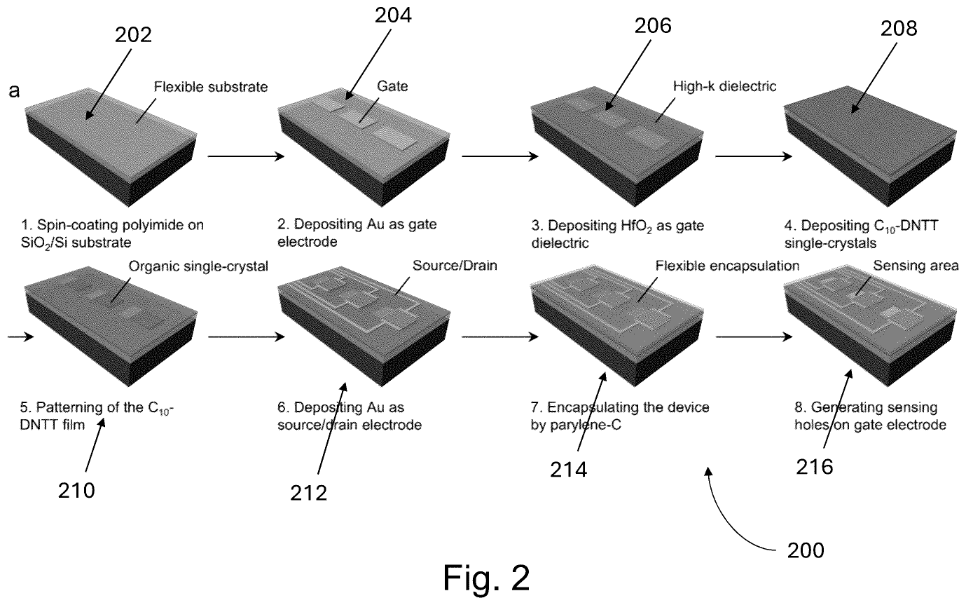

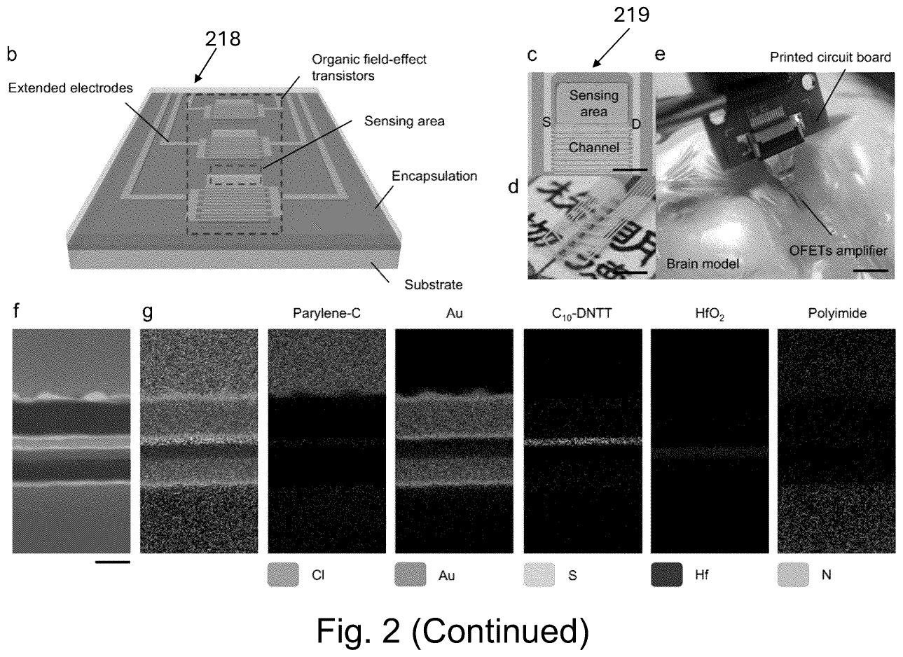

Preferably, the device 100 is constructed on a multilayer flexible stack engineered for biocompatibility, low-voltage operation, and high transconductance. As shown in FIG. 2, part G, as shown from top layer to the bottom layer, the structure of the device 100 includes a parylene-C encapsulation layer 220 that provides hydrophobic protection while leaving an exposed gold sensing pad 222 for neural interfacing. Beneath this pad 222 lies a C10-DNTT organic single-crystal semiconductor 224, deposited as four molecular layers using a controlled solution shearing process to ensure large area crystallinity. In some embodiments, the source and drain electrodes are formed from 50 nm gold in a bottom-contact configuration. A high-κ HfO₂ gate dielectric 226, deposited by atomic layer deposition to a thickness of 16 nm, provides high areal capacitance and supports low-voltage OFET operation. The entire stack is built on a polyimide (PI) flexible substrate 228, with thickness tuned so that the final device remains under 10 μm in total thickness.

In some examples, as shown with reference to FIG. 2, fabrication process 200 of the device 100 begins by spin-coating and annealing the PI substrate on a carrier wafer 202. The gold gate electrode is then deposited 204, followed by ALD growth of the HfO₂ dielectric 206. The C10-DNTT semiconductor layer is formed by solution shearing, with blade speed and temperature adjusted to achieve the desired four-layer single-crystal film 208.

The organic semiconductor is then patterned using photoresist and O₂ reactive-ion etching 210, after which the gold source and drain electrodes are defined by evaporation and lift-off 212, yielding a channel length of approximately 5 μm. A parylene-C encapsulation layer is deposited over the device 214, and reactive-ion etching is used to open the sensing pad and electrical connection vias 216. Finally, the device is mounted onto a PCB using an SU-8 holder and released from the carrier wafer, producing a thin, flexible active electrode suitable for conformal neural interfacing.

The invention provides a flexible, organic transistor based active electrode that performs on-site amplification of neural signals to address the limitations of conventional passive and ion-gated electrodes. Functionally, the device uses an organic single-crystal C10-DNTT active layer in an OFET configuration, combined with a high-κ HfO₂ gate dielectric and a short-channel design of approximately 5 μm. The single-crystal semiconductor eliminates grain boundaries, thereby improving charge mobility and lowering access resistance relative to polycrystalline films, which in turn increases on-current and transconductance (gm). The high-κ HfO₂ dielectric provides high areal capacitance, enabling low-voltage operation and further enhancing transconductance per unit gate voltage. Together, these features allow the OFET to deliver strong on-site amplification of microvolt-level neural signals.

The device 100 may also be implemented in a resistive-loaded inverter topology with DC offset tuning, forming a compact, low-power analogue amplifier. By applying a controlled DC offset, the inverter transition point is aligned with neural baseline potentials so that small microvolt-scale inputs fall within the high-gain region of the transfer characteristic. This arrangement increases the signal-to-noise ratio (SNR) at the point of acquisition, mitigating signal degradation that typically occurs when weak signals are transmitted from passive electrodes to remote amplifiers. The thin, ultra-conformal form factor achieved by keeping the total device thickness below 10 μm allows the electrode to conform closely to curved brain surfaces, improving electrical coupling, reducing motion artifacts, and enhancing recording stability during physiological movement. Parylene-C encapsulation with an exposed gold sensing pad isolates the transistor stack from ionic fluids while leaving only the sensing interface in contact with the tissue. The hydrophobic and biocompatible nature of parylene-C also improves device lifetime and reliability in liquid and biological environments such as those of insertions into the skull of the patient or subject.

The device 100 may be advantageous as examples of these structural and circuit-level features collectively address several concerns in neural interfacing. First, by amplifying signals directly at the brain surface, the device 100 overcomes signal degradation and low SNR inherent to passive microelectrodes, which otherwise pick up microvolt-level signals that are easily corrupted during transmission to external amplifiers. Second, the use of a solid HfO2 dielectric in an OFET architecture avoids the ion-transport limitations of organic electrochemical transistors (OECTs) and other ion-gated devices. While OECTs can exhibit high (gm), their reliance on ion motion leads to bandwidth constraints, hysteresis, and slower response at kilohertz range frequencies. In contrast, the solid-state OFET stack supports higher cut-off frequencies and reduced hysteresis, enabling reliable recording of both low frequency field potentials and higher frequency spike activity.

Further advantages may arise from the mechanical and electrochemical design of the device 100. Rigid silicon electronics are mechanically mismatched to soft brain tissue, which can cause poor contact and chronic tissue irritation or inflammation. The combination of a thin polyimide substrate, which is biocompatible, parylene-C encapsulation, and an organic semiconductor yields a flexible, conformal device that better matches the mechanical properties of neural tissue, thereby improving tissue contact and reducing mechanical stress.

Additionally, the solid dielectric and low gate leakage characteristics of the HfO2 layer minimize ionic currents into the tissue, with picoampere-level gate currents targeted. This reduces the risk of electrochemical damage and enhances long-term recording stability compared with ion-penetrating devices. In turn, examples of the device 100 may offer a balanced solution that combines high-bandwidth, low-voltage amplification with mechanical compliance, biocompatibility, and improved safety for chronic neural recording applications.

With reference to FIG. 2, the structural components and fabrication method of the neural signal amplification device are illustrated. FIG. 2, (a) shows the step-by-step fabrication procedures 200. The device 100 is constructed upon a substrate 202 which, preferably, includes a flexible polymeric material, such as, but not limited to polyimide (PI). Polyimide is an advantageous material as it has biocompatible properties. In this example, the polyimide is arranged to have a thickness of less than 10 μm. Additionally, Polyimide is preferable as it is flexible, has high thermal stability, good mechanical properties, and low surface roughness and in turn provides a flat and suitable platform for subsequent layer deposition. This ultra-thin, flexible nature also allows the device to conformally attach to the curvilinear surface of a subject's brain (as shown in the images of FIG. 2 part (d) and FIG. 2 part (e). In turn, reducing mechanical mismatch and potential tissue damage during insertion, testing and usage.

To enable high-performance operation of the device 100, a gate electrode (Au) is deposited 204, followed by a gate dielectric layer 206. Preferably, the gate dielectric comprises a solid dielectric material such as a high-κ metal oxide. The material used may include hafnium oxide (HfO₂) deposited by atomic layer deposition (ALD). The deposition of high-κHfO₂ is preferable to enhance the transconductance (gₘ) and to decrease the operation voltage of the device 100. Furthermore, the use of a solid high-κ dielectric is advantageous and more unique from ionic-gated devices (such as OECTs), enabling high operating speeds (high frequency) and low leakage currents. In preferred embodiments, the HfO₂ layer on the sensing area is clearly etched by reactive ion etching (RIE). This etching step ensures that brain signals may be completely input into the OFETs without attenuation by the dielectric layer at the sensing interface.

The semiconductor layer is subsequently formed. As shown at 208, this layer comprises an organic single-crystal structure, specifically 2,9-didecyldinaphtho [2,3-b: 2,3′-f] thieno[3,2-b] thiophene (C₁₀-DNTT). As shown in FIG. 2 part (a) at 208, the C₁₀-DNTT is deposited via solution shearing process. This process is arranged to align the molecular layers to minimize grain boundaries within the channel region.

Following deposition, the organic single-crystal is patterned 210 to eliminate fringe currents and downscale the off-current. By combining photolithography with the organic single crystal, a short channel device (approximately 5 μm channel length in some examples) may be achieved without grain boundaries, exhibiting higher on-current and gm. FIG. 2 at parts (b) and (c) illustrate the detailed schematic structure 218 and optical image of the device 219, respectively. The source and drain electrodes 212 may also be arranged to extend away from the gate (sensing area) for connection to a printed circuit board (PCB). This physical separation may assist to minimize electrical crosstalk between the weak neural signals at the gate and the driving currents at the source/drain electrodes, further improving signal fidelity.

Preferably, the device 100 is encapsulated to ensure stability and biocompatibility. Accordingly, an encapsulation layer comprising Parylene-C covers the OFET and amplification element 214 but includes an opening exposing only the sensing pad of the gate (Au) with sensing holes 216. This encapsulation layer minimizes crosstalk between the brain and the source/drain electrodes. The hydrophobic surface of the Parylene-C, characterized, in some examples, by a water contact angle of approximately 105°, contributes to protecting the device when working in a liquid environment (e.g., cerebrospinal fluid) and prevents ion penetration into the channel.

As shown in FIG. 2 part (f) and (g), there is shown a cross-sectional analysis of the layers of the device 100. In part (f), there is a rendered scanning transmission electron microscopy (STEM) image exhibiting the layered structure. In part (g), there is shown a corresponding energy-dispersive X-ray spectroscopy (EDS) result which maps out the elemental distribution and thus show the corresponding the OFET layers of the device 100. The Chlorine (Cl) element represents the Parylene-C encapsulation; the gold (Au) element represents the source/drain/gate electrodes; the Sulphur(S) element represents the C₁₀-DNTT channel; the Hafnium (Hf) element represents the HfO₂ dielectric; and the Nitrogen (N) element represents the PI substrate.

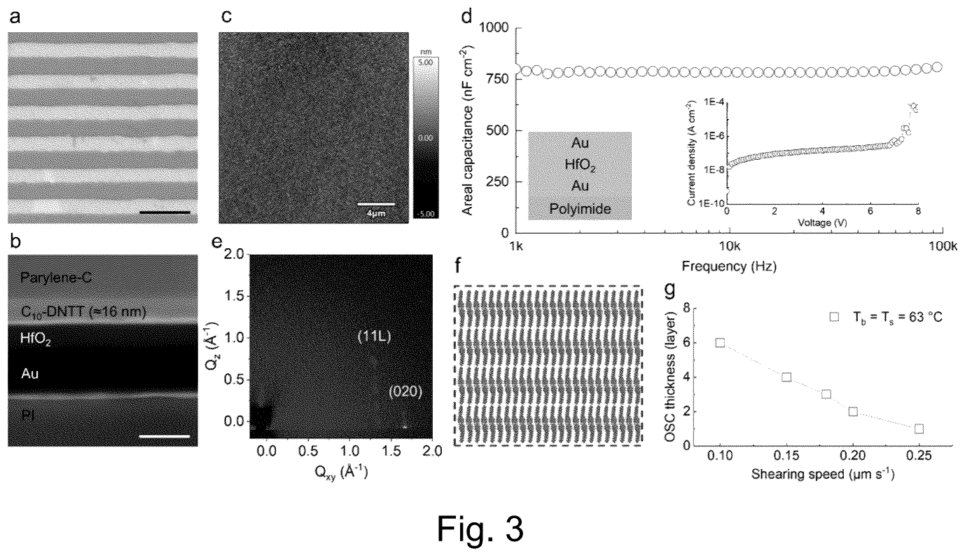

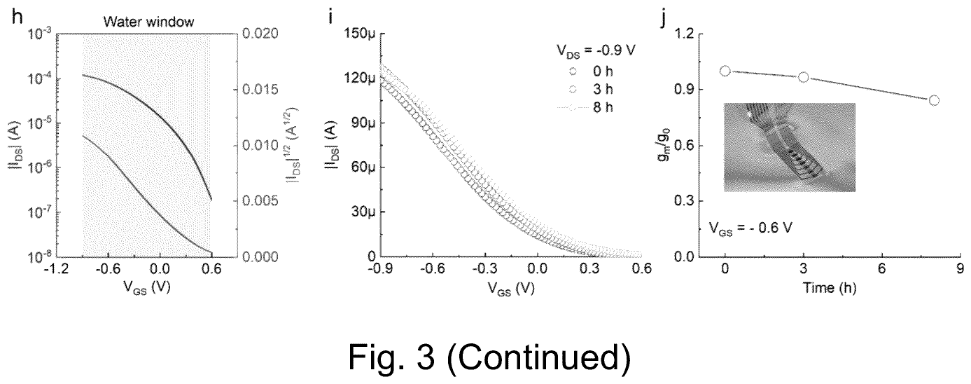

With reference to FIG. 3, the material and electrical characteristics of the fabricated OFETs are further described. As show in FIG. 3 part (a), the image shows a polarized optical microscope (POM) image of the OFETs, confirming the single-crystal nature of the organic semiconductor channel. The device features a channel length of approximately 5 μm, which contributes to the high transconductance observed. FIG. 3 part (b) provides a rendered scanning transmission electron microscopy (STEM) image of the channel regime, further illustrating the structural integrity of the device stack.

The quality of the interface between the substrate, dielectric, and semiconductor is critical for device performance. As shown in the atomic force microscopy (AFM) image in FIG. 3 part (d), the polyimide (PI) substrate exhibits a low surface roughness (R_{q}=0.8 nm). This smooth surface provides a flat platform essential for the deposition of the C₁₀-DNTT by solution shearing, as the growth of the organic single-crystal may be highly sensitive to surface energy and roughness. FIG. 3 at part (c) highlights the performance of the high-κHfO₂ gate dielectric. Using a metal-insulator-metal (MIM) structure (Au/HfO₂/Au/PI) as shown in the inset of FIG. 3 (d), the areal capacitance (Cᵢ) is deduced to be 799 nF cm⁻² under 1 kHz and 1 V bias. This high capacitance may facilitate the transistor to operate within a smaller voltage range. Preferably, the device 100 operates with a leakage current density through the gate dielectric of less than 10⁻⁷A cm⁻² (shown in the inset of FIG. 3 (c)). This extremely low leakage current is important and preferable for biocompatibility, ensuring that the device does not electrically stimulate or damage the brain tissue during recording.

To verify the crystallinity, the inventors performed 2D Grazing-Incidence Wide-Angle X-ray Scattering (GIWAXS). The result in FIG. 3 (e) indicates the distinct (11L) and (020) planes of the C₁₀-DNTT, confirming the formation of a high-quality single crystal structure which supports enhanced charge carrier mobility. In FIG. 3 (f), there is illustrated the molecular packaging strategy. Preferably, the semiconductor layer comprises a multilayer stack of C₁₀-DNTT molecules. While monolayer or bilayer films may offer lower access resistance, these are susceptible to thermal damage from ion bombardment during the subsequent deposition of source/drain electrodes. Therefore, a thickness of four molecular layers is optionally selected as the active layer. This specific thickness is optimized by precisely controlling the shearing parameters; specifically, with both the blade and substrate temperatures set to 63 degrees C, the relationship between shearing speeds and organic semiconductor thickness is plotted in the chart at FIG. 3 part (g). The electrical transfer characteristics are shown in FIG. 3 (h). A typical double-sweep transfer curve in the saturation regime (V_{DS}=−0.9V) is displayed, with a gate sweep range from 0.6 V to −0.9 V to remain within the water window limit. The device exhibits a negligible hysteresis, which is a significant improvement over ionic-gated transistors (IGTs) like OECTs that typically suffer from hysteresis due to ion trapping. This negligible hysteresis indicates a compact contact interface between the HfO₂and C₁₀-DNTT. Finally, the long-term stability of the device is evaluated in a physiological environment. At FIG. 3 part (i), the chart plots the transfer curves of the OFETs after storage in a 1×PBS environment for 8 hours. As indicated in FIG. 3 part (j), the transconductance (gm) is well-preserved, maintaining over 84% of its original value. The slight discrepancy in on-current and gm is attributed to charge accumulation on the Au surface causing a slight threshold voltage shift, yet the device 100 remains robust for neural recording applications.

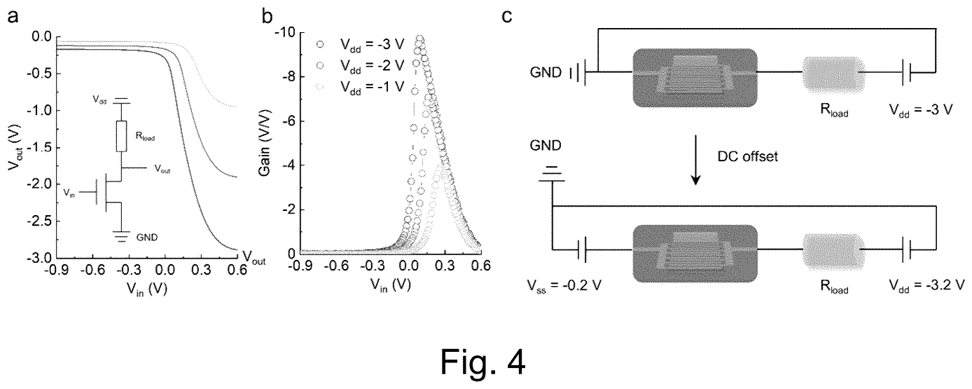

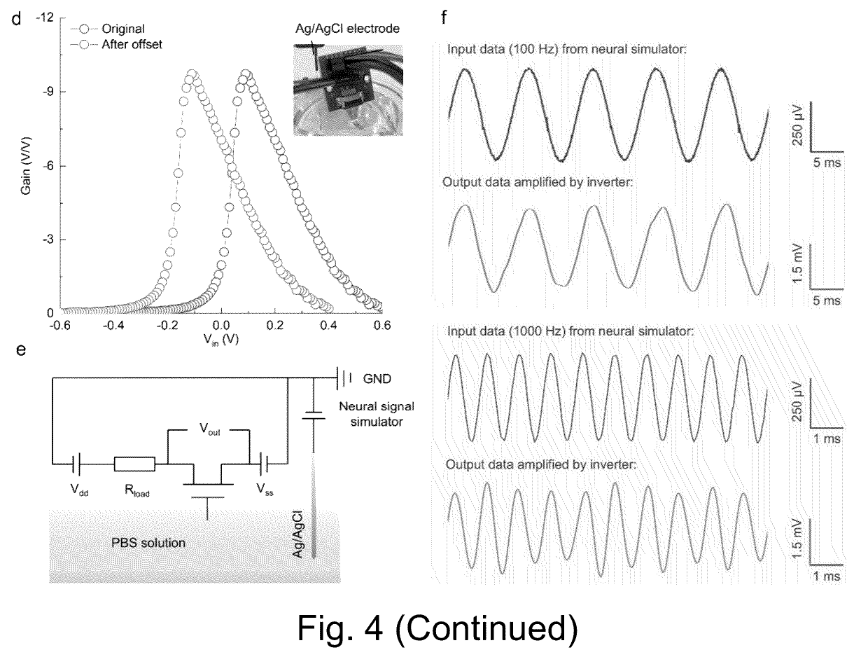

With reference to FIG. 4, the operation of the device 100 as an amplifier was demonstrated through in-vitro testing. FIG. 4 at part (a) displays the voltage transfer curves of the resistive-loaded inverter under different drive voltages (Vdd) and inset diagram indicates the circuit structure. To maximize the amplification gain, the load element comprises a resistor having a resistance value matched to the on-resistance of the OFET. Deduced from the resistance of the OFETs, a 510 kΩ resistor is utilized as this load resistor. As shown in FIG. 4 part (b), the gain of the inverter reaches approximately 10 when driven at a V_{dd} of −3 V. A critical operational challenge and its solution are illustrated in FIG. 4 part (c) and FIG. 4 part (d). As seen in FIG. 4 (b), the transition voltage of the inverter is naturally located around 0.2 V. This value may not be aligned with the input level of typical brain signals, which fluctuate around a 0 V baseline (mV level). If left uncorrected, the amplification may be sufficiently sacrificed because the amplifier may not be operating in its steepest, most linear region for the neural signals. To correct this misalignment, a DC offset voltage source is coupled to the amplification element. As indicated in the schematic in FIG. 4 part (c), a bias of −0.2 V is applied to the source/drain terminals of the inverter (shifting the left terminal from 0 V to −0.2 V and the right terminal from −3 V to −3.2 V). Consequently, as shown in FIG. 4 part (d), the transition voltage is successfully shifted to align with the 0 V baseline, ensuring the amplifier operates in its highest gain region for the incoming neural signals. FIG. 4 part (e) shows the circuit diagram for the in-vitro evaluation, where a neural signal simulator is used to generate input signals. FIG. 4 part (f) demonstrates the practical signal processing capabilities of the invention. Preferably, the device 100 is arranged to provide a voltage gain of at least 6 times for neural signals. Using a high sampling rate of 20,000 sps to capture fast transients, the figure compares input signals with an amplitude of 250 μV against the amplified output signals which have an amplitude of 1.5 mV (a sixfold amplification). Notably, the device successfully amplifies signals at both 100 Hz (typical of Local Field Potentials or ECoG) and 1 kHz (typical of high-frequency neural spikes). Furthermore, within a 0.25 V input range, the inverter achieves over 5 times amplification, offering improved tolerance to variations in device uniformity and stability.

In a practical surgical setting, a neurosurgeon could place the flexible device 100 directly onto the cortex of a patient. Due to the solid dielectric and high-mobility single crystal channel, the device would be capable of recording high-frequency single-unit activity (spikes) which are often lost by slower, ionic-based active electrodes. The on-site amplification provided by the inverter circuit would boost these microvolt-level spikes before they travel through the wiring to external equipment, thereby preserving the signal quality against environmental noise in the operating room and in the subsequent observation process.

### Example Experiment

The inventors produced an example embodiment of the neural signal amplification device and proceeded to test it under specific conditions. The processes and results are described below.

Materials: Si/SiO₂ wafer was bought from Namkang Hi-Tech. C₁₀-DNTT was purchased from Luminescence Technology Corp.

Fabrication of substrate, gate, and dielectric layer: Polyimide (PI) was spin-coated on Si/SiO₂ wafer by 4000 rpm to serve as substrate and annealed in N₂ and vacuum environment under 350° C. for 40 mins, respectively. Then, a 30 nm gold (Au) film was deposited by thermal evaporation (Kurt J. Lesker Company, Mini SPECTROS-Thermal) on PI through a shadow mask. After that, 16 nm high-κ dielectric hafnium oxide (HfO₂) was deposited by atomic layer deposition (Kurt J. Lesker Company, ALD-150LE™).

Solution-shearing of C₁₀-DNTT single crystal: The solution-shearing process was conducted with available equipment. 1 mg C₁₀-DNTT powder was firstly dissolved in 5 mL tetralin, and the 0.2 mg mL⁻¹ solution was sonicated for 10 mins followed by being heated overnight under 68° C. before solution-shearing. Then, 35 μL solution was injected into the 100 μm gap between the blade and substrate, and the blade/substrate temperatures were set to 63° C. during the process. The solution shearing speed for 16 nm C₁₀-DNTT was found to be 2.5 μm s⁻¹. After that, the sample was stored in a vacuum environment overnight to fully remove the solvent residue.

Organic semiconductor patterning and source/drain deposition: The C₁₀-DNTT film was patterned by OSCoR 5020 photoresist (Orthogonal Inc.) and O₂ reactive ion etching (RIE) (SUSS MA/BA6 Gen4; Oxford PlasmaPro 100 Cobra). OSCoR 5020 photoresist was used to define source/drain contacts followed by thermal evaporation of 50 nm Au (W/L=2000, L=5 μm) and lift-off. Finally, the specimen was stored in a vacuum environment overnight to remove the solvent.

Encapsulation, etching, and printed circuit board (PCB) connection: 2.6 g parylene-C was deposited (Specialty Coating Systems, PDS 2010) on the specimen to serve as the encapsulation layer. Firstly, the probe shape was defined by AZ nLOF 2070 photoresist and etched by RIE (10 min (O₂) for the parylene layer, 3 min (O₂+CF₄) for the HfO₂ layer, and 30 min (O₂) for the PI layer). After that, the PCB connection holes, and sensing holes were also defined by AZ nLOF 2070 and etched by RIE (10 min (O₂) for the parylene layer and 3 min (O₂+CF₄) for the HfO₂ layer (only sensing holes regime)). Then, SU8 photoresist (KAYAKU Advanced Materials) was used to fabricate the device holder. Finally, after storage in a vacuum for 1 week, the device was peeled off from the Si/SiO₂ substrate and inserted into the PCB assistant with SU8 and PI film.

Characterization and measurement: The cross-sectional scanning transmission electron microscope (STEM) characterization of the organic field-effect transistors (OFETs) stack was performed by FEI Quanta 200 3D Focused Ion Beam and Thermo Scientific Talos F200X STEM. The polarized optical image of C₁₀-DNTT was captured by Nikon Eclipse LV100N. The atomic force microscopy of PI was inquired by Oxford Cypher Asylum Research AFM. The 2D Grazing-Incidence Wide-Angle X-ray Scattering was conducted by Rigaku SmartLab X-Ray with copper target. The electrical performance of the OFETs was done by Agilent B1500A Semiconductor Device Analyzer and Keithley DMM6500. The input signals were generated by Blackrock Digital Neural Signal Simulator PN-8282. The output data from the inverter was filtered by customized programs in MATLAB.

The example flexible OFETs-based active electrode for on-site brain signal amplification offers an advantageous performance over existing electrodes. By integrating solution-processed organic single-crystal on the high-κ gate dielectric, the flexible device 100 as tested by the inventors'example experiments exhibits a high gₘ of 149 μS and good stability in a liquid environment. On the benefit of these properties, the 250 μV amplitude signals (100 Hz and 1 kHz) are amplified over 6 times by the resistive-loaded inverter. Additionally, the device is encapsulated by biocompatible materials, indicating that it is reliable for in-vivo monitoring.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

Any reference to prior art contained herein is not to be taken as an admission that the information is common general knowledge, unless otherwise indicated.

1. A neural signal amplification device comprising:
a substrate having an organic field-effect transistor (OFET) disposed on the substrate, the OFET having a gate arranged to receive neural signals and a gate dielectric layer disposed between the gate and a semiconductor layer, wherein the OFET is arranged to amplify the neural signals received at the gate.

2. The device of claim 1, wherein the substrate comprises a flexible polymeric material arranged to conform to a surface of a subject's brain.

3. The device of claim 1, wherein the gate dielectric layer comprises a solid dielectric material arranged to electrically isolate biological tissue from the semiconductor layer.

4. The device of claim 1, wherein the semiconductor layer comprises an organic single-crystal structure arranged to provide enhanced charge-carrier mobility.

5. The device of claim 1, wherein the OFET is electrically coupled to a load element to amplify the neural signals received at the gate; and wherein the load element when coupled to the OFET defines an inverter-type amplifier circuit.

6. The device of claim 1, wherein the organic single-crystal structure of the semiconductor layer comprises 2,9-didecyldinaphtho[2,3-b:2,3′-f]thieno[3,2-b]thiophene (C10-DNTT).

7. The device of claim 6, wherein the solid dielectric material comprises a high-κ metal oxide.

8. The device of claim 7, wherein the high-κ metal oxide comprises hafnium oxide (HfO₂) deposited by atomic layer deposition.

9. The device of claim 8, wherein the organic single-crystal structure comprises a solution sheared film having aligned molecular layers to minimize grain boundaries within a channel region defined between a source electrode and a drain electrode of the OFET.

10. The device of claim 9, further comprising an encapsulation layer covering the OFET and an electrically coupled load element, the encapsulation layer having an opening exposing a portion of the gate to define a sensing area for contact with biological tissue.

11. The device of claim 10, wherein the encapsulation layer comprises Parylene-C having a thickness of less than 10 μm.

12. The device of claim 11, wherein the OFET defines a channel length of approximately 5 μm between a source electrode and a drain electrode.

13. The device of claim 12, further comprising a DC offset voltage source coupled to the amplification element and arranged to shift a transition voltage of the amplification element to align with a baseline voltage of the neural signals.

14. The device of claim 13, wherein the load element comprises a resistor having a resistance value matched to an on-resistance of the OFET.

15. The device of claim 13, wherein a source electrode and a drain electrode of the OFET are extended away from the gate to reduce electrical crosstalk between the neural signals and driving currents of the OFET.

16. The device of claim 15, wherein the semiconductor layer comprises a multilayer stack of C10-DNTT molecules.

17. The device of claim 16, wherein the multilayer stack comprises four molecular layers.

18. A method of fabricating a neural amplification device of claim 1, comprising the steps of:
spin coating polyimide (PI) onto a SiO2/Si wafer as a flexible substrate;
depositing electrodes, including a gate onto the PI;
depositing a high-κ hafnium oxide (HfO2) over the PI and the electrodes;
depositing C10-DNTT single crystals onto the high-κ HfO2;
solution shearing the C10-DNTT single crystals;
patterning the solution sheared organic single-crystals using photolithography;
depositing source/drain electrodes;
etching the HfO2 on the sensing area at the gate; and
encapsulating the device with biocompatible materials whilst leaving a sensing area at the gate exposed.

19. The method of claim 18 wherein the encapsulating biocompatible material is parylene-C.

20. The method of claim 18, wherein the electrodes are formed by depositing gold onto the PI.
